(19) United States
(12) Patent Application Publication
(10) Pub. No.: US 2026/0143978 A1
(43) Pub. Date: May 21, 2026

(54) METHOD OF SELECTIVELY DEPOSITING MATERIAL ON NON-METALLIC SURFACE

(71) Applicant: ASM IP Holding B.V., Almere (NL)

(72) Inventors: Kristina Paula Martinez, Phoenix, AZ (US); Adam Vianna, Phoenix, AZ (US); Krzysztof Kamil Kachel, Queen Creek, AZ (US); Marko Tuominen, Helsinki (FI); Eva Elizabeth Tois, Espoo (FI); Saima Ali, Helsinki (FI); Bhagyesh Purohit, Vantaa (FI); Charles Dezelah, Helsinki (FI)

(21) Appl. No.: 19/386,352

(22) Filed: Nov. 12, 2025

Related U.S. Application Data
(60) Provisional application No. 63/721,265, filed on Nov. 15, 2024.

(51) Int. Cl. H01L 21/02; C23C 16/04; C23C 16/455; C23C 16/52

(52) U.S. Cl. CPC H10P 14/6502; C23C 16/045; C23C 16/45544; C23C 16/45553; C23C 16/52; H10P 14/6334

(57) ABSTRACT

A method of selectively depositing a material on a non-metallic surface relative to a metallic surface is disclosed. An exemplary method includes using a reactant to selectively form an inhibitor layer on the metallic surface and subsequently depositing the material on the non-metallic surface.

### CROSS-REFERENCE TO RELATED APPLICATIONS

This application is a nonprovisional of, and claims priority to and the benefit of, U.S. Provisional Patent Application No. 63/721,265, filed Nov. 15, 2024 and entitled “METHOD OF SELECTIVELY DEPOSITING MATERIAL ON NON-METALLIC SURFACE,” which is hereby incorporated by reference herein.

### FIELD OF INVENTION

The present disclosure generally relates to methods for depositing material on a substrate. More particularly, the disclosure relates to selectively depositing material on a surface utilizing a selectively formed passivation film.

### BACKGROUND OF THE DISCLOSURE

During the formation of devices, such as semiconductor devices, it is often desirable to form patterned features on a surface of a substrate. Typically, to form the regions or features, a layer or film of material is deposited onto a surface of a substrate. The deposited layer is then patterned using, for example, photolithography and etch processes to remove portions of the layer to form desired features or areas including the remaining material. As device features continue to decrease in size, it becomes increasingly difficult to pattern and etch material films to form features or areas of patterned material of desired dimensions, particularly when it is desired to deposit material within a via or trench on a substrate surface. Additionally, lithography and etch steps can increase costs associated with device manufacturing and increase an amount of time required for device fabrication.

Accordingly, improved methods are desired for selectively forming material on portions of a substrate surface.

### SUMMARY OF THE DISCLOSURE

This section introduces a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure provide methods and reactor systems for selectively depositing material on a non-metallic surface relative to a metallic surface. As set forth in more detail below, the selective deposition can be obtained by selectively forming an inhibitor or blocking or passivation layer on the metallic surface relative to the non-metallic surface. The inhibitor layer can prevent or mitigate unwanted deposition of material on the metallic surface.

In accordance with various embodiments of the disclosure, a method of selectively depositing a material on a non-metallic surface relative to a metallic surface is provided, the method including providing a substrate within a reaction chamber of a reactor, the substrate including the non-metallic surface and the metallic surface; and providing a reactant to the reaction chamber, wherein the reactant selectively reacts with the metallic surface, relative to the non-metallic surface, to form an inhibitor layer, wherein the reactant is represented by a general formula:

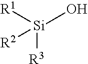

where each of R1, R2, and R3 is independently selected from a C1-C10 linear or branched or cyclic hydrocarbon or a C1-C10 linear or branched or cyclic alkoxide, and wherein at least one of R1, R2, and R3 is a C1-C10 linear or branched hydrocarbon.

In some embodiments, the metallic surface includes a native oxide.

In some embodiments, each of R1, R2, and R3 is a C1-C10 linear or branched hydrocarbon.

In some embodiments, at least one of R1, R2, and R3 is a C1-C10 linear or branched or cyclic alkoxide.

In some embodiments, at least one of R1, R2, and R3 is a tertpentoxy ligand.

In some embodiments, at least one of R1, R2, and R3 is a tertpentyl ligand.

In some embodiments, each of R1, R2, and R3 is fully saturated.

In some embodiments, the method further includes selectively depositing the material on the non-metallic surface.

In some embodiments, the material includes dielectric material.

In some embodiments, the material includes a metal nitride, a metal oxide, a metal oxynitride, or a metal carbide.

In some embodiments, selectively depositing the material on the non-metallic surface includes forming a barrier layer.

In some embodiments, the method further includes a step of removing the inhibitor layer.

In some embodiments, the substrate includes a gap, and the material is selectively deposited on a surface within the gap.

In some embodiments, the surface includes a sidewall of the gap.

In some embodiments, the non-metallic surface includes a silicon oxide, a silicon nitride, a silicon oxynitride, a silicon carbide, a doped silicon, silicon germanium, or a doped silicon germanium.

In some embodiments, the method does not include a step of removing a native oxide from the metallic surface.

In accordance with various embodiments of the disclosure, a method of selectively depositing a material on a non-metallic surface relative to a metallic surface is provided, the method including providing a substrate within a reaction chamber of a reactor, the substrate including the non-metallic surface and the metallic surface; and providing a reactant to the reaction chamber, wherein the reactant selectively reacts with the metallic surface, relative to the non-metallic surface, to form an inhibitor layer, wherein the reactant is represented by a general formula:

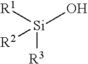

where each of R1, R2, and R3 is independently selected from a C1-C10 linear or branched or cyclic hydrocarbon or a C1-C10 linear or branched or cyclic alkoxide, wherein at least one of R1, R2, and R3 is a C1-C10 linear or branched fully saturated hydrocarbon, and wherein the material includes a metal nitride, a metal oxide, a metal oxynitride, or a metal carbide.

In some embodiments, the non-metallic surface includes metalloid or a metal oxide or a metal nitride or a metal carbide.

In some embodiments, the metallic surface includes a native oxide that is not removed immediately prior to the step of providing the reactant to the reaction chamber.

In accordance with various embodiments of the disclosure, a reactor system is provided including a first reaction chamber; a second reaction chamber; a source vessel including the reactant and coupled to the first reaction chamber; a controller configured to perform the claimed method; and a vacuum source.

Both the foregoing summary and the following detailed description are exemplary and explanatory only and are not restrictive of the disclosure or the claimed invention.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a method in accordance with various embodiments of the disclosure.

FIG. 2 illustrates a substrate and a substrate surface in accordance with various embodiments of the disclosure.

FIGS. 3 and 4 illustrate selective deposition on a gap on a substrate surface in accordance with various embodiments of the disclosure.

FIG. 5 illustrates method steps in accordance with additional embodiments of the disclosure.

FIG. 6 illustrates a reactor system in accordance with additional exemplary embodiments of the disclosure.

FIG. 7 illustrates deposition rate of material on metallic and non-metallic surfaces in accordance with further examples of the disclosure.

It will be appreciated that elements in the figures are illustrated for simplicity and clarity and have not necessarily been drawn to scale. For example, the dimensions of some of the elements in the figures may be exaggerated relative to other elements to help to improve the understanding of illustrated embodiments of the present disclosure.

### DETAILED DESCRIPTION OF EXEMPLARY EMBODIMENTS

The description of exemplary embodiments provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features.

As set forth in more detail below, various embodiments of the disclosure relate to a method of selectively depositing a material on a non-metallic surface relative to a metallic surface. The method can form selectively deposited material on the non-metallic surface without patterning and etching steps.

Selectivity can be described as a percentage calculated as [(amount of deposition on a first surface)−(amount of deposition on a second surface)]/(amount of deposition on the first surface). Additionally or alternatively, selectivity can be defined as a ratio of material deposited on a first (e.g., non-metallic) surface: an amount of material deposited on a second (e.g., metallic) surface. An amount of deposition can be, for example, a measured thickness of the deposited material or a mass of the deposited material.

As used herein, the term substrate may refer to any underlying material or materials, including and/or upon which material can be deposited. A substrate can include a bulk material, such as silicon (e.g., single-crystal silicon), other Group IV materials, such as germanium, or compound semiconductor materials, such as GaAs, and can include one or more layers overlying or underlying the bulk material. For example, a substrate can include a patterning stack of several layers overlying bulk material. The patterning stack can vary according to application. Further, the substrate can include various gaps, such as recesses, vias, spaces between lines, trenches, and the like formed on the surface of the substrate. In accordance with various examples, the substrate includes a non-metallic surface and a metallic surface.

As used herein, the term metallic surface may refer to surfaces including a metal component, including, but not limited to, metal surfaces, metal alloy surfaces, and other surfaces that include a metal and that are conductive (e.g., have a resistivity of less than 100 μΩcm). In some cases, the term metallic surface may include a surface of native oxide of a metal. In some cases, the metal surface consists of a metallic material. In some cases, the metallic surface consists essentially of one or more of a metal or a metal alloy. In some embodiments, the metallic surface is an electrically conductive surface. In some embodiments, the metallic surface comprises a transition metal. In some embodiments, the metallic surface comprises elemental metal. In some embodiments, the metallic surface is elemental metal.

In some embodiments, the metallic surface comprises elemental tungsten. In some embodiments, the metallic surface is elemental tungsten. In some embodiments, the metallic surface comprises elemental cobalt. In some embodiments, the metallic surface is elemental cobalt. In some embodiments, the metallic surface comprises titanium nitride. In some embodiments, the metallic surface is titanium nitride. In some embodiments, the metallic surface comprises tantalum nitride. In some embodiments, the metallic surface is tantalum nitride. In some embodiments, the metallic surface comprises aluminum nitride. In some embodiments, the metallic surface is aluminum nitride. An elemental metal surface may comprise surface oxidation.

In some embodiments, the metallic surface comprises a metal selected from a group consisting of Ti, V, Nb, Ta, Cr, Mo, W, Mn, Fe, Co, Ni, Cu, Zn, Ru and Al. Thus, in some embodiments, the metallic surface comprises titanium. In some embodiments, the metallic surface comprises vanadium. In some embodiments, the metallic surface comprises niobium. In some embodiments, the metallic surface comprises tantalum. In some embodiments, the metallic surface comprises chromium. In some embodiments, the metallic surface comprises molybdenum. In some embodiments, the metallic surface comprises tungsten. In some embodiments, the metallic surface comprises manganese. In some embodiments, the metallic surface comprises iron. In some embodiments, the metallic surface comprises cobalt. In some embodiments, the metallic surface comprises nickel. In some embodiments, the metallic surface comprises copper. In some embodiments, the metallic surface comprises zinc. In some embodiments, the metallic surface comprises ruthenium. In some embodiments, the metallic surface comprises aluminum.

In some embodiments, the metallic surface comprises elemental titanium. In some embodiments, the metallic surface comprises elemental vanadium. In some embodiments, the metallic surface comprises elemental niobium. In some embodiments, the metallic surface comprises elemental tantalum. In some embodiments, the metallic surface comprises elemental chromium. In some embodiments, the metallic surface comprises elemental molybdenum. In some embodiments, the metallic surface comprises elemental tungsten. In some embodiments, the metallic surface comprises elemental manganese. In some embodiments, the metallic surface comprises elemental iron. In some embodiments, the metallic surface comprises elemental cobalt. In some embodiments, the metallic surface comprises elemental nickel. In some embodiments, the metallic surface comprises elemental copper. In some embodiments, the metallic surface comprises elemental zinc. In some embodiments, the metallic surface comprises elemental ruthenium. In some embodiments, the metallic surface comprises elemental aluminum.

In some embodiments, a metallic surface comprises titanium nitride. In some embodiments, the metallic surface comprises one or more noble metals, such as Ru. In some embodiments, the metallic surface comprises a conductive metal oxide. In some embodiments, the metallic surface comprises a conductive metal nitride. In some embodiments, the metallic surface comprises a conductive metal carbide. In some embodiments, the metallic surface comprises a conductive metal boride. In some embodiments, the metallic surface comprises a combination of conductive materials. For example, the metallic surface may comprise one or more of ruthenium oxide (RuOx), niobium carbide (NbCx), niobium boride (NbBx), nickel oxide (NiOx), cobalt oxide (CoOx), niobium oxide (NbOx), tungsten carbonitride (WNCx), tantalum nitride (TaN), or titanium nitride (TiN).

As used herein, the term non-metallic surface may refer to a surface including primarily non-metal and/or non-conductive (e.g., resistivity greater than 500 ohm-cm) material. Exemplary non-metallic surfaces can be or include metalloids and/or an oxide, nitride, or carbide thereof. In some cases, the non-metallic surface is or includes a metalloid or a metal oxide or a metal nitride or a metal carbide. By way of example, the non-metallic surface can include one or more silicon containing materials, such as, for example, silicon, a silicon oxide, a silicon nitride, a silicon oxynitride, a silicon carbide, a doped silicon, silicon germanium, a doped silicon germanium, mixtures thereof, or the like.

In some embodiments, the non-metallic surface may be a SiO₂-based surface. In some embodiments, the non-metallic surface may comprise Si—O bonds. In some embodiments, the non-metallic surface may comprise a SiO₂-based low-k material. In some embodiments, the non-metallic surface may comprise more than about 30%, or more than about 50% of SiO₂. In some embodiments, the non-metallic surface may comprise a silicon oxide surface.

In some embodiments, the metallic surface is a metal surface, and the non-metallic surface is a SiO₂ surface. In some embodiments, the metallic surface is a metal surface, such as an elemental metal surface, and the non-metallic surface is a SiN surface. In some embodiments, the metallic surface is a metal surface, and the non-metallic surface is a SiOC surface. In some embodiments, the metallic surface is a metal surface, and the non-metallic surface is a SiON surface. In some embodiments, the metallic surface is a metal surface, and the non-metallic surface is a SiOCN surface. The metallic surface may be, for example, a copper surface, a ruthenium surface, a tungsten surface, a cobalt surface, or a molybdenum surface. In some embodiments, the metallic surface comprises a conductive metal oxide. In some embodiments, the metallic surface comprises aluminum oxide. In some embodiments, a metal oxide surface is an oxidized surface of a metallic material. In some embodiments, a metal oxide surface is created by oxidizing at least the surface of a metallic material using oxygen compound, such as compounds comprising O₃, H₂O, H₂O₂, O₂, oxygen atoms, plasma or radicals or mixtures thereof. In some embodiments, a metal oxide surface is a native oxide formed on a metallic material.

In some embodiments, the term film refers to a layer extending in a direction perpendicular to a thickness direction. In some embodiments, layer refers to a material having a certain thickness formed on a surface or a synonym of film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. Further, a layer or film can be continuous or discontinuous.

In this disclosure, the term gas may refer to material that is a gas at normal temperature and pressure, a vaporized solid and/or a vaporized liquid, and may be constituted by a single gas or a mixture of gases, depending on the context. A gas other than the process gas, i.e., a gas introduced without passing through a gas distribution device, such as a showerhead, other gas distribution device, or the like, may be used for, e.g., sealing the reaction space, and may include a seal gas, such as a rare gas.

The term cyclic deposition process or cyclical deposition process may refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, an inert gas and/or one or more reactants can continuously flow during multiple cycles of a cyclical process, and a precursor can be pulsed. In accordance with examples of the disclosure, the method includes a thermal cyclical deposition process. Such a process does not include use of a plasma or the like to excite the precursor and/or reactant. Rather, such processes typically employ a substrate heater or other heater to drive the desired reactions.

In this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like, in some embodiments. For example, the term about can refer to +/−20, 10, 5, 2, or 1 percent of a value. Further, in this disclosure, the terms including constituted by and having and their equivalents can refer independently to typically or broadly comprising, comprising, consisting essentially of, or consisting of in some embodiments. In accordance with aspects of the disclosure, any defined meanings of terms do not necessarily exclude ordinary and customary meanings of the terms.

A number of example materials are given throughout the embodiments of the current disclosure. It should be noted that the chemical formulas given for each of the example materials should not be construed as limiting and that the non-limiting example materials given should not be limited by a given example stoichiometry.

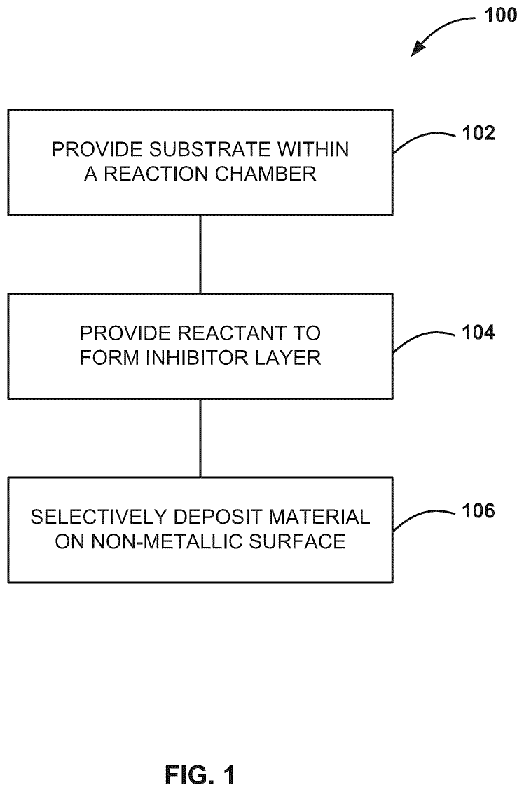

Turning now to the figures, FIG. 1 illustrates a method 100 of selectively depositing a material on a non-metallic surface relative to a metallic surface in accordance with embodiments of the disclosure. Method 100 includes the steps of providing the substrate within a reaction chamber of a reactor (step 102), providing a reactant to the reaction chamber (step 104), and selectively depositing the material on the non-metallic surface (step 106).

During step 102, a substrate is provided within a reaction chamber. The substrate includes a surface that includes a metallic surface and a non-metallic surface. As noted above, the metallic surface can include a native oxide. In some cases, method 100 does not include a step of removing a native oxide from the metallic surface. In some cases, the metallic surface comprises a native oxide that is not removed immediately prior to the step of providing a reactant to the reaction chamber.

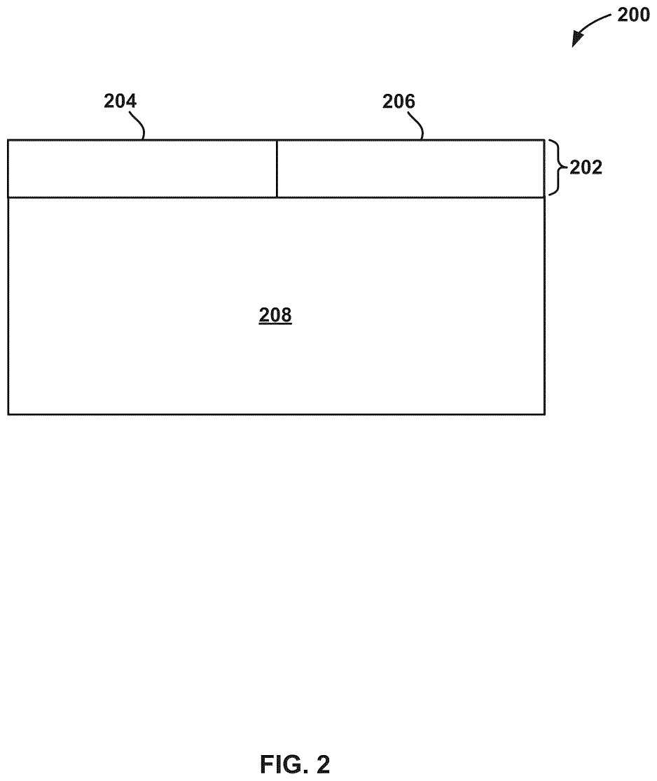

FIG. 2 illustrates an exemplary substrate 200 suitable for use with various embodiments of the disclosure. Substrate 200 includes a surface 202 that includes a metallic surface 204 and a non-metallic surface 206. In accordance with examples of the disclosure, non-metallic surface 206 comprises —OH terminal groups. In the illustrated example, substrate 200 also includes bulk material 208. As noted above, substrates can also include various layers and topologies that are not separately illustrated.

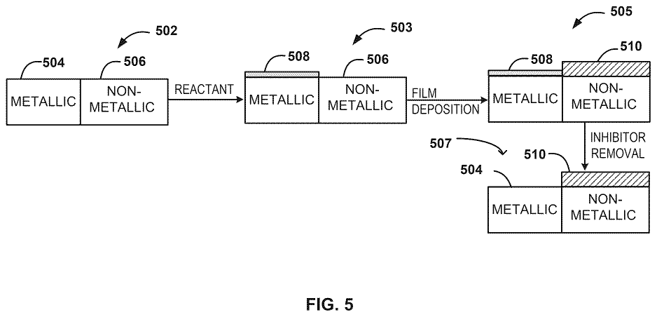

Returning to FIG. 1, the reaction chamber used during step 102 can be or include a reaction chamber of a chemical vapor deposition reactor system configured to perform a cyclical deposition process. The reaction chamber can be a standalone reaction chamber or part of a cluster tool. An exemplary reaction chamber is described in more detail below in connection with FIG. 5.

Step 102 can include heating the substrate to a desired deposition temperature within the reaction chamber. In some embodiments of the disclosure, step 102 includes heating the substrate to a temperature of less than 800° C. For example, in some embodiments of the disclosure, heating the substrate to a deposition temperature may comprise heating the substrate to a temperature between about 20° C. and about 800° C., less than 650° C., less than 600° C., less than 550° C., less than 500° C., between about 300° C. and 600° C., between about 300° C. and 650° C., between about 300° C. and 550° C., between about 300° C. and 500° C., or between about 100° C. and 300° C.

In addition to controlling the temperature of the substrate, a pressure within the reaction chamber may also be regulated. For example, in some embodiments of the disclosure, the pressure within the reaction chamber during step 102 and/or at a beginning of step 104 may be less than 1200 Torr or less than 760 Torr or between about 0.001 and about 300 Torr, about 5 and about 250 Torr, or about 1 and about 70 Torr.

During step 104, a reactant is provided to the reaction chamber. During this step, the reactant selectively reacts with the metallic surface, relative to the non-metallic surface, to form an inhibitor layer on the metallic surface.

In some embodiments, selectivity is at least about 50%. In some embodiments, selectivity is at least about 75% or greater than about 85%. In some embodiments, selectivity is at least about 90% or at least about 93%. In some embodiments, selectivity is at least about 95% or at least about 98%. In some embodiments, selectivity is at least about 99% or even at least about 99.5%. In embodiments, the selectivity can change over the duration or thickness of a deposition. In some embodiments, a ratio of material deposited on the metallic surface relative to the non-metallic surface may be greater than or equal to 200:1, or greater than or equal to 100:1, or greater than or equal to 50:1, or greater than or equal to 25:1, or greater than or equal to 20:1, or greater than or equal to 15:1, or greater than or equal to 10:1, or greater than or equal to 5:1, or greater than or equal to 3:1, or greater than or equal to 2:1. In some embodiments, the selectively deposited inhibitor layer may have a thickness less than 50 nanometers, or less than 20 nanometers, or less than 10 nanometers, or less than 5 nanometers, or less than 3 nanometers, or less than 2 nanometers, or less than 1 nanometer, or between approximately 1 nanometer and 50 nanometers.

A temperature during step 104 can be as described above in connection with step 102. A pressure within the reaction chamber can also be as described above in connection with step 102. A flowrate of the reactant, alone, can be between about 0.01 and about 1000 sccm or between about 1 and about 5 sccm. A flowrate of the reactant with a carrier gas can be between about 1 sccm and about 50 SLM or between about 2 sccm and about 5 SLM or between about 1 SLM and about 5 SLM. A duration of step 104 can be between about 0.1 seconds and about 3 hours, between about 0.1 seconds and about 2 hours, or between about 0.1 seconds and about 300 seconds. In some cases, step 104 can include a soak process, in which a throttle valve between the reaction chamber and a vacuum source is at least partially closed during step 104. In some cases, a pressure within the reaction chamber is allowed to build during step 104. In some cases, the reactant can be periodically pulsed to the reaction chamber during the soak period to refresh the reactant. In some cases, the reaction chamber can be periodically pumped down during the soak period.

In accordance with examples of the disclosure, the reactant is or includes a silanol. Exemplary compounds suitable for use with step 104 include a silicon bonded to at least one —OH group. Particular examples of suitable reactants are represented by a general formula:

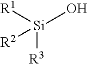

where each of R¹, R², and R³ is independently selected from a C1-C10 linear or branched or cyclic hydrocarbon or a C1-C10 linear or branched or cyclic alkoxide, and wherein at least one of R¹, R², and R³ is a C1-C10 linear or branched hydrocarbon. In some cases, at least one of R¹, R², and R³ is a C9 or C10 hydrocarbon. In accordance with examples of the disclosure, at least one (e.g., one or two) of R¹, R², and R³ is a C1-C10 linear or branched or cyclic alkoxide. In accordance with further examples, each of R¹, R², and R³ is a C1-C10 linear or branched hydrocarbon. By way or particular examples, at least one (e.g., one or two) of R¹, R², and R³ is a tertpentoxy ligand and/or at least one (e.g., one or two or three) of R¹, R², and R³ is a tertpentyl ligand. In accordance with yet further examples, each of R¹, R², and R³ is fully saturated. Additional exemplary reactants and material are disclosed in U.S. application Ser. No. 18/889,069, filed Sep. 18, 2024 and entitled SELECTIVE DEPOSITION OF ORGANIC POLYMER MATERIAL AND DEPOSITION ASSEMBLIES, the contents of which are hereby incorporated herein by reference to the extent such contents do not conflict with the present disclosure.

The reactant can be provided to the reaction chamber using a carrier gas. Suitable carrier gases include inert gases, such as argon, helium, nitrogen, any combination thereof, and the like.

At the completion of step 104, an inhibitor layer is formed on the metallic surface (e.g., metallic surface 204), compared to the non-metallic surface (e.g., surface 206). FIG. 5 illustrates a substrate surface 502 that includes a metallic surface 504 and a non-metallic surface 506. During step 104, substrate surface 502 is exposed to the reactant, which selectively reacts with the metallic surface 504 to form surface 503, which includes non-metallic surface 506 and an inhibitor layer 508.

During step 106, the material is selectively deposited onto the non-metallic surface relative to the inhibitor layer/metallic surface. Referring again to FIG. 5, a surface 505 includes inhibitor layer 508 and material 510.

The material (e.g., material 510) can be, for example, a dielectric material. In some cases, the material (e.g., material 510) comprises a metal nitride, a metal oxide, a metal oxynitride, a metal carbide, or any combination thereof. In some cases, the material (e.g., material 510) comprises a barrier material and the deposited material forms a barrier layer.

The dielectric material can be material having a dielectric constant greater than 3.9 or greater than a dielectric constant of silicon oxide. In accordance with examples of the disclosure, the material is or includes a metal oxide, nitride, or carbide or a metalloid oxide, nitride, or carbide. The metal can be, for example, a transition or post transition metal, such as aluminum, hafnium, yttrium, titanium, tantalum, titanium nitride, molybdenum, tungsten, combinations thereof or the like. The metalloid can be or include, for example, silicon, germanium, silicon germanium, gallium, arsenic, or the like.

In some cases, the material can be conductive. For example, the material can be or include a conductive metal oxide, nitride, or carbide. In such cases, the deposited material can be a barrier layer. In these cases, a subsequent layer of metal, such as a metal noted above, can be deposited onto the barrier layer.

Step 106 can be or include a cyclical deposition process that includes providing a metal or metalloid precursor and a reactant to the reaction chamber. Exemplary metal or metalloid precursors include organometalloid and organometallic precursors, such as organoaluminum, organosilicon, organoyttrium precursor, or the like. Exemplary reactants for material deposition include oxidizing, nitriding, and/or carbonizing reactants.

Exemplary oxidizing agents include one or more of O2, water (H2O), hydrogen peroxide (H2O2), ozone (O3), oxides of nitrogen, such as, for example, nitrogen monoxide (NO), nitrous oxide (N2O), and nitrogen dioxide (NO2).

Exemplary nitriding agents can be selected from one or more of nitrogen (N2), ammonia (NH3), hydrazine (N2H4) or a hydrazine derivate, a mixture of hydrogen and nitrogen, nitrogen ions, nitrogen radicals, and excited nitrogen species, and other nitrogen and hydrogen-containing gases. The nitrogen reactant can include or consist of nitrogen and hydrogen. In some cases, the nitrogen reactant does not include diatomic nitrogen.

Exemplary carbonizing agents include acetylene, ethylene, alkyl halide compounds, alkene halide compounds, metal alkyl compounds, and the like. Exemplary alkyl halide compounds include CX4, CHX3, CH2X2, CH3X, where X═F, Cl, Br, or I. Exemplary alkene halide compounds include C2H3X, C2H2X2, C2HX3, and C2X4, where X═F, Cl, Br, or I. Exemplary alkyne halide compounds include C2X2 and HC2X, where X═F, Cl, Br, or I. Exemplary metal alkyl compounds include AlMe3, AlEt3, Al(iPr)3, Al(iBu)3, Al(tBu)3, GaMe3, GaEt3, Ga(iPr)3, Ga(iBu)3, Ga(tBu)3, InMe3, InEt3, In(iPr)3, In(iBu)3, In(tBu)3, ZnMe2, and ZnEt2.

In some embodiments, the deposition of material only occurs on the non-metallic surface and does not occur on the inhibitor layer/metallic surface. In some embodiments, deposition selectivity of the material on the non-metallic surface relative to the inhibitor layer/metallic surface is at least about 80%. In some embodiments, deposition selectivity of the material on the non-metallic surface relative to the inhibitor layer/metallic surface is at least about 90%. In some embodiments, deposition selectivity of the material on the non-metallic surface relative to the inhibitor layer/metallic surface is at least about 98%. In some cases, the selectivity can be about 100% to a thickness of greater than 5 nm, greater than 10 nm, or greater than 15 nm.

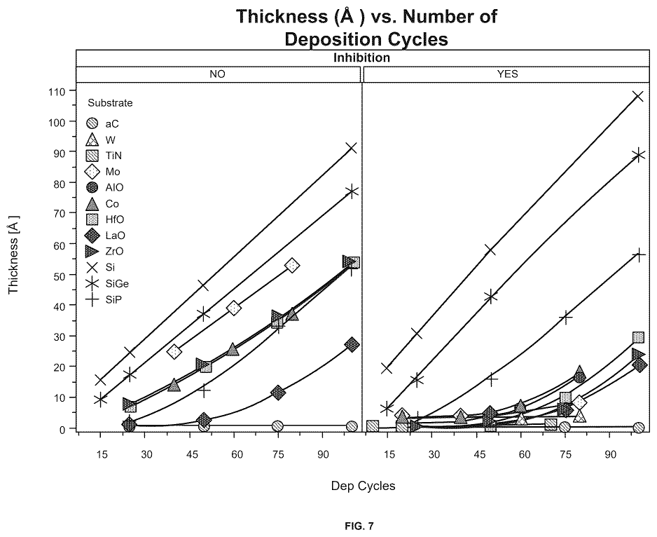

FIG. 7 illustrates selectivity of material (e.g., aluminum oxide) of various substrates, including amorphous carbon, silicon, aluminum oxide, cobalt, molybdenum, titanium nitride, tungsten, and other materials. As with other figures, FIG. 7 is used to illustrate examples of the disclosure and is not meant to limit the scope of the claims. As illustrated, deposition on silicon (non-metallic surface) using a method described herein is much higher than deposition of material on the other surfaces.

As illustrated in FIG. 5, a method can also include a step of removing the inhibitor layer to form a surface 507 that includes metallic surface 504 and material 510. The inhibitor layer can be removed after the step of selectively depositing the material on the metal surface. The inhibitor layer removal step can include a plasma process. By way of examples, the inhibitor layer removal step can include a hydrogen and/or nitrogen and/or oxygen-based direct, indirect, or remote plasma process or the like. In some cases, a method does not include an inhibitor layer removal step.

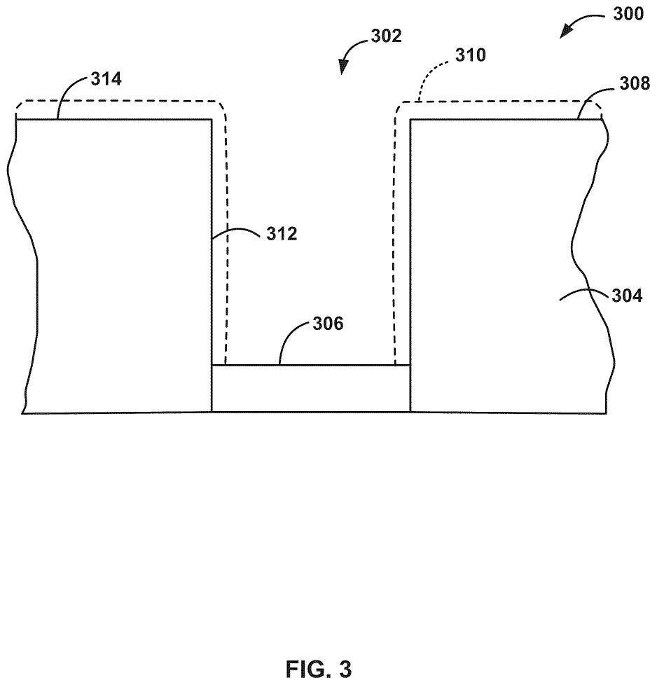

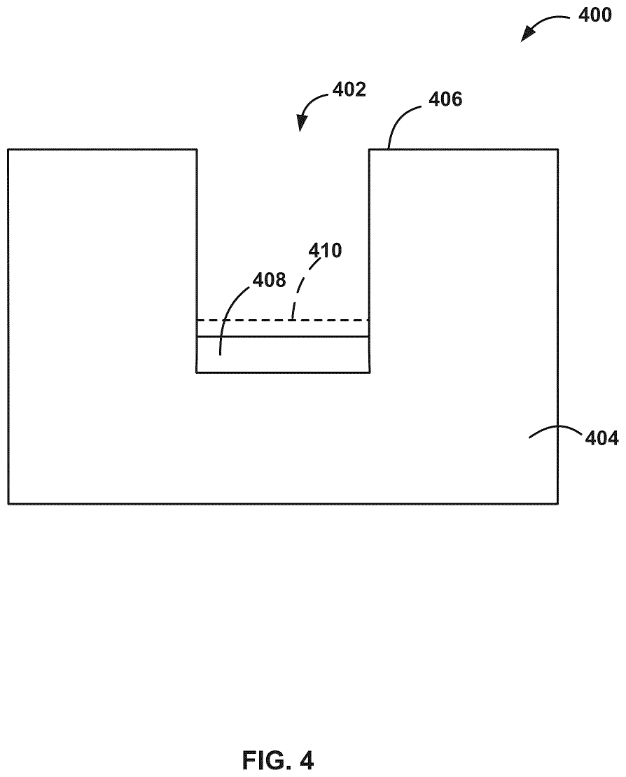

In accordance with further examples of the disclosure, the substrate includes a gap, such as gap 302, illustrated in FIG. 3, or gap 402, illustrated in FIG. 4. In accordance with examples of the disclosure, material deposited during step 106 is selectively deposited on a (e.g., non-metallic) surface within the gap.

FIG. 3 illustrates a structure 300 that includes gap 302 formed on a surface of a substrate 304. Substrate 304 includes a metallic surface 306 and a non-metallic surface 308. Material 310 is selectively deposited onto non-metallic surface 308 using a method as described herein. In these cases, material 310 is selectively deposited on sidewall(s) 312 and/or a top surface 314 of gap 302. In some cases, material 310 can be used to form a spacer and/or repair or expand sidewall(s) 312 and/or top surface 314.

FIG. 4 illustrates a structure 400 that includes gap 402 formed on a surface of a substrate 404. Substrate 404 includes a metallic surface 406 and a non-metallic surface 408. Material 410 is selectively deposited onto non-metallic surface 408 using a method as described herein. In these cases, material 410 can be used to at least partially fill gap 402 from the bottom up.

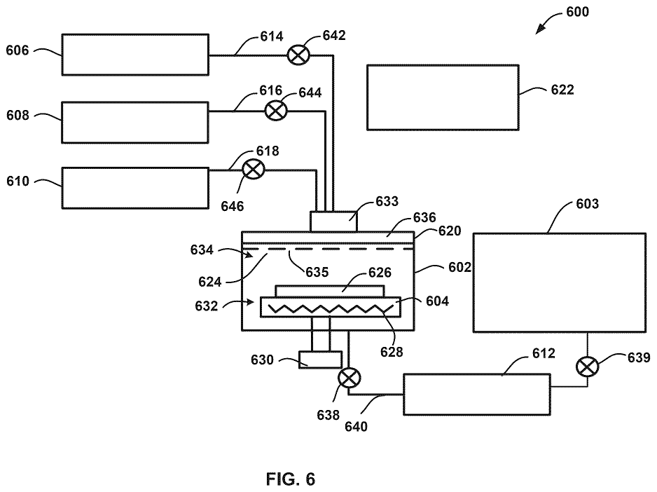

FIG. 6 illustrates an exemplary reactor system 600 in accordance with additional exemplary embodiments of the disclosure. Reactor system 600 includes a first reactor 602, a second reactor 603, a susceptor 604, gas sources 606-610, a gas distribution device 620, vacuum source 612, and controller 622. Second reactor 603 can be configured similarly to reactor 602 and can be coupled to vacuum source 612 via a valve 639 and/or to controller 622. Although not illustrated, reactor system 600 may additionally include direct and/or remote plasma and/or thermal excitation apparatus for one or more reactants and/or precursors within reactor 602.

Reactor 602 can include a reaction chamber 624 suitable for gas-phase reactions. Reactor 602 can be formed of suitable material, such as quartz, metal, or the like, and can be configured to retain one or more substrates for processing. Reactor system 600 can include any suitable number of reactors 602 and can optionally include one or more substrate handling systems. Reactor 602 can be a standalone reactor or part of a cluster tool.

Reactor 602 can be configured as a cyclical deposition process reactor (e.g., a cyclical CVD reactor), an ALD reactor, or the like. Reactor 602 can be configured to deposit a variety of films or layers, such as the inhibitor layer and/or the material noted above.

Susceptor 604 is configured to retain substrate 626 in place during processing. One or more sections of susceptor 604 can be heated, cooled, or be at ambient process temperature during processing. In accordance with examples of the disclosure, susceptor 604 includes a temperature regulating device 628, such as a heater (e.g., a resistive heater), and/or a cooling device (e.g., a conduit for a cooling medium, such as chilled water).

In the illustrated example, reactor system 600 includes a mechanism 630 to move susceptor 604 from a lower chamber region 632 to an upper chamber region 634. Mechanism 630 can include any suitable apparatus capable of moving susceptor 604. By way of example, mechanism 630 includes a servo motor to drive susceptor 604 along a vertical axis. Mechanism 630 can suitably reside outside reaction chamber 624.

Susceptor 604 can be formed of any suitable material, such as ceramic material, such as boron nitride, aluminum nitride, quartz, and ceramic-coated materials, such as ceramic-coated metals. Susceptor 604 can also include resistive heating material. Exemplary materials suitable for resistive heating material include tungsten (W), nichrome (NiCr), cupronickel (CuNi), graphite, molybdenum disilicide (MoSi₂) or any other suitable heater material. The resistive heating material can be coated onto (e.g., patterned onto), for example, ceramic or ceramic-coated metal. Susceptor 604 can include an additional protective layer formed overlying the resistive heating material. The protective layer can be formed of, for example, ceramic material.

Gas sources 606-610 can include any suitable vessels and respective material contained therein. By way of examples, gas source 606 can include the reactant, gas source 608 can include a precursor for the material, and gas source 610 can include an inert gas and/or a reactant for material deposition. Gas sources 606-610 can be coupled to reaction chamber 624 via gas distribution device 620.

Gas distribution device 620 is configured to receive and facilitate distribution of one or more gases to reaction chamber 624 during substrate processing. Gas distribution device 620 can include an inlet 633 and a plurality of holes 635 coupled to a plenum 636.

Vacuum source 612 can include one or more vacuum sources. Exemplary vacuum sources include one or more dry vacuum pumps and/or one or more turbomolecular pumps. A (e.g., throttle) valve 638 can be in a line that fluidly couples reaction chamber 624 to vacuum source 612.

Controller 622 can be configured to perform various functions and/or steps as described herein. For example, controller 622 can be configured to perform the method described in connection with FIG. 1. Controller 622 can include one or more microprocessors, memory elements, and/or switching elements to perform the various functions. Although illustrated as a single unit, controller 622 can alternatively comprise multiple devices. By way of examples, controller 622 can be used to control gas flow of one or more gases from sources 606-610 via one or more of lines 614, 616, 618 and valves 642, 644, 646, to move susceptor 604 between a first position, to control a pressure within reaction chamber 624 (e.g., using valve 638), and/or to provide a reactant and/or a precursor (e.g., using one or more of valves 642-646) as described herein.

Although exemplary embodiments of the present disclosure are set forth herein, it should be appreciated that the disclosure is not so limited. For example, although the reactors, systems, and methods are described in connection with various specific configurations, the disclosure is not necessarily limited to these examples. Various modifications, variations, and enhancements of the exemplary reactors, systems, and methods set forth herein may be made without departing from the spirit and scope of the present disclosure.

The subject matter of the present disclosure includes all novel and nonobvious combinations and subcombinations of the various steps, systems, reactors, components, and configurations, and other features, functions, acts, and/or properties disclosed herein, as well as any and all equivalents thereof.

1. A method of selectively depositing a material on a non-metallic surface relative to a metallic surface, the method comprising:
providing a substrate within a reaction chamber of a reactor, the substrate comprising the non-metallic surface and the metallic surface; and
providing a reactant to the reaction chamber, wherein the reactant selectively reacts with the metallic surface, relative to the non-metallic surface, to form an inhibitor layer,
wherein the reactant is represented by a general formula: 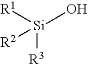
where each of R¹, R², and R³ is independently selected from a C1-C10 linear or branched or cyclic hydrocarbon or a C1-C10 linear or branched or cyclic alkoxide, and
wherein at least one of R¹, R², and R³ is a C1-C10 linear or branched hydrocarbon.

2. The method of claim 1, wherein the metallic surface comprises a native oxide.

3. The method of claim 1, wherein each of R¹, R², and R³ is a C1-C10 linear or branched hydrocarbon.

4. The method of claim 1, wherein at least one of R¹, R², and R³ is a C1-C10 linear or branched or cyclic alkoxide.

5. The method of claim 1, wherein at least one of R¹, R², and R³ is a tertpentoxy ligand.

6. The method of claim 1, wherein at least one of R¹, R², and R³ is a tertpentyl ligand.

7. The method of claim 1, wherein each of R¹, R², and R³ is fully saturated.

8. The method of claim 1, further comprising selectively depositing the material on the non-metallic surface.

9. The method of claim 8, wherein the material comprises dielectric material.

10. The method of claim 8, wherein the material comprises a metal nitride, a metal oxide, a metal oxynitride, or a metal carbide.

11. The method of claim 8, wherein selectively depositing the material on the non-metallic surface comprises forming a barrier layer.

12. The method of claim 1, further comprising a step of removing the inhibitor layer.

13. The method of claim 1, wherein the substrate comprises a gap, and wherein the material is selectively deposited on a surface within the gap.

14. The method of claim 13, wherein the surface comprises a sidewall of the gap.

15. The method of claim 1, wherein the non-metallic surface comprises a silicon oxide, a silicon nitride, a silicon oxynitride, a silicon carbide, a doped silicon, silicon germanium, or a doped silicon germanium.

16. The method of claim 1, wherein the method does not include a step of removing a native oxide from the metallic surface.

17. A method of selectively depositing a material on a non-metallic surface relative to a metallic surface, the method comprising:
providing a substrate within a reaction chamber of a reactor, the substrate comprising the non-metallic surface and the metallic surface; and
providing a reactant to the reaction chamber, wherein the reactant selectively reacts with the metallic surface, relative to the non-metallic surface, to form an inhibitor layer,
wherein the reactant is represented by a general formula: 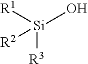
where each of R¹, R², and R³ is independently selected from a C1-C10 linear or branched or cyclic hydrocarbon or a C1-C10 linear or branched or cyclic alkoxide,
wherein at least one of R¹, R², and R³ is a C1-C10 linear or branched fully saturated hydrocarbon, and
wherein the material comprises a metal nitride, a metal oxide, a metal oxynitride, or a metal carbide.

18. The method of claim 17, wherein the non-metallic surface comprises metalloid or a metal oxide or a metal nitride or a metal carbide.

19. The method of claim 17, wherein the metallic surface comprises a native oxide that is not removed immediately prior to the step of providing the reactant to the reaction chamber.

20. A reactor system comprising:
a first reaction chamber;
a second reaction chamber;
a source vessel comprising the reactant and coupled to the first reaction chamber;
a controller configured to perform the method of claim 1; and
a vacuum source.
